(19) United States
(12) Patent Application Publication
(10) Pub. No.: US 2024/0355595 A1
(43) Pub. Date: Oct. 24, 2024

(54) LOW PARAMETER PLASMA ASHING TECHNIQUES

(71) Applicant: Micron Technology, Inc., Boise, ID (US)

(72) Inventors: Rachmat Wibowo, Singapore (SG); Mohd Kamran Akhtar, Boise, ID (US); Grady S. Waldo, Boise, ID (US)

(21) Appl. No.: 18/634,430

(22) Filed: Apr. 12, 2024

Related U.S. Application Data
(60) Provisional application No. 63/497,453, filed on Apr. 21, 2023.

(51) Int. Cl. H01J 37/32

(52) U.S. Cl. CPC H01J 37/32724; H01J 37/32816; H01J 2237/327; H01J 2237/3341

(57) ABSTRACT

Methods, systems, and devices for low parameter plasma ashing techniques are described. The method may include performing an etching process on a substrate comprising a photoresist layer. In some cases, the method may include selecting at least a temperature of a clamp for holding the substrate, a temperature of a process chamber configured to perform the plasma ashing process, a pressure of the process chamber, and a power of a plasma source based at least in part on performing the etching process. The method may further include generating a plasma that comprises oxygen, applying the plasma to the photoresist layer, and exposing the photoresist layer of the substrate to the plasma at the selected temperature, pressure, and power to at least partially remove the photoresist layer from the substrate.

### CROSS REFERENCE

The present application for patent claims the benefit of U.S. Provisional Patent Application No. 63/497,453 by WIBOWO et al., entitled “LOW PARAMETER PLASMA ASHING TECHNIQUES,” filed Apr. 21, 2023, assigned to the assignee hereof, and expressly incorporated by reference in its entirety herein.

### TECHNICAL FIELD

The following relates to one or more systems for memory, including low parameter plasma ashing techniques.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source. Some memory devices may be formed by forming a plurality of layers, performing an etching process, and/or performing a plasma ashing process. The plasma ashing process may be performed to remove at least a portion of the plurality of layers.

### BRIEF DESCRIPTION OF THE DRAWINGS

FIG. 1 shows an example of a system that supports low parameter plasma ashing techniques in accordance with examples as disclosed herein.

FIG. 2 shows an example of a system that supports low parameter plasma ashing techniques in accordance with examples as disclosed herein.

FIG. 3 shows an example of a process flow that supports low parameter plasma ashing techniques in accordance with examples as disclosed herein.

FIG. 4 shows a block diagram of a system that supports low parameter plasma ashing techniques in accordance with examples as disclosed herein.

FIGS. 5 and 6 show flowcharts illustrating a method or methods that support low parameter plasma ashing techniques in accordance with examples as disclosed herein.

### DETAILED DESCRIPTION

Some electronic devices may be formed, at least in part, by forming a substrate and forming an additional layer on top of the substrate. The additional layer may be an example of a photoresist layer in some examples. The photoresist layer may include a light-sensitive material of hydrocarbon polymers that may be used to form a patterned coating on top of the substrate. In some examples, the photoresist layer may be exposed to a light source such that a portion of the photoresist layer may be removed and a portion of the substrate may be exposed. An etching process may then be performed to remove the exposed portion of the substrate. After the etching, the remaining portions of the photoresist layer may be removed.

A plasma ashing process may remove the photoresist layer from the surface of the substrate. The plasma ashing process may include using a plasma source to apply a reactive species (e.g., a plasma) to the surface of the photoresist layer such that the material of the photoresist layer reacts with the reactive species and is removed from the surface of the substrate.

However, the plasma ashing process may be performed at high temperatures, high power, and/or high pressure that may contribute to a substrate surface oxidation. Despite the effectiveness of performing the plasma ashing process with oxygen plasma to etch away carbon-based layers like the photoresist layer and other residues, performing the plasma ashing process at high temperatures of oxidizing chemistry may increase an amount of substrate surface oxidation. Substrate surface oxidation may be an example of oxide growth on the surface of the substrate. The oxide growth may increase a rate of metal corrosion of the substate and cause a substrate loss of underlying layers. In some cases, the substrate surface oxidation may result in a bridging defect at a shallow trench isolation (STI) trench, decrease contact resistance, and contribute to downstream process contamination from peeling defects. In some cases, the plasma ashing process may use ammonia (NH₃), forming gas (H₂N₂), or both. However, ammonia and forming gas may yield the formation of a solid ammonium nitrate (AN) by-product in pump exhaust systems that can cause a safety risk concern or be challenging to manage. In addition, using ammonia or forming gas may increase the rate of system parts failure thereby increasing the cost and decreasing the lifetime of the system.

To reduce the amount of substrate surface oxidation, among other benefits, the plasma ashing process may be performed using a parameters controlled component, such as a temperature controlled component, for example a chuck, operating at lower variable parameter values, such as temperatures. In some cases, the plasma ashing process may be performed using low temperature, low pressure, low power, or any combination thereof to reduce the substrate surface oxidation and minimize the effects on underlying layers. For example, the system may enable a low temperature strip process (e.g., plasma ashing process) to strip the photoresist layer, a polymer layer, and/or a residue without affecting or removing underlying layers (e.g., the substrate, a metal exposed layer, low dielectric materials, and the like) while also preventing the formation of the AN by-product. The temperature controlled chuck may be modified by one or more process conditions instead of a static hardware setting.

The system may include a process chamber configured to perform the plasma ashing process. The process chamber may include the chuck configured to hold the substrate and operate at a selected temperature, a selected pressure, and/or a selected power, among other parameters. The process chamber may include a plasma source configured to generate the plasma that includes oxygen, and may include a baffle plate configure to diffuse the plasma from the plasma source over the chuck at the selected temperature, the selected pressure, and the selected power. The system may perform the etching process on the substrate that includes the photoresist layer. The system may be configured to select at least a temperature of the chuck for performing the etching process. In some cases, the system may select a temperature of the process chamber, a pressure of the process chamber, and a power of a plasma source, among other parameters. Based on selecting the temperature, pressure, power, or any combination thereof, the system may generate the plasma and apply the plasma to the photoresist layer, thereby exposing the photoresist layer to the plasma at the selected temperature, selected pressure, and/or selected power. In such cases, the photoresist layer may be at least partially removed from the surface of the substrate while minimizing the amount of substrate surface oxidation.

By selecting a lower temperature, pressure, power, or any combination thereof to perform the plasma ashing process, the system (e.g., including at least the process chamber, chuck, and plasma source) may operate to effectively remove the photoresist layer and prevent oxide growth on the substrate, thereby increasing the overall efficiency of the plasma ashing process and increasing the lifetime of the system. In some cases, performing the plasma ashing process at lower temperatures may prevent the formation of the AN by-product, decrease an amount of corrosion of the substrate and underlying layers, and prevent a bridging defect of the STI trench. The system may also experience process improvements by reducing substrate loss and increasing contact resistance between components of the electronic device, thereby allowing the electronic device or other components to perform operations at improved speeds, efficiency, and performance.

In addition to applicability in memory systems as described herein, techniques for low temperature plasma ashing may be generally implemented to improve the sustainability of various electronic devices and systems. As the use of electronic devices has become even more widespread, the quantity of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing materials used in production of electronic devices and eliminating additional production processes to remove the substrate surface oxidation, which may result in lowered production emissions, reduce electronic waste, extend the life of electronic devices and thereby reducing electronic waste, among other benefits.

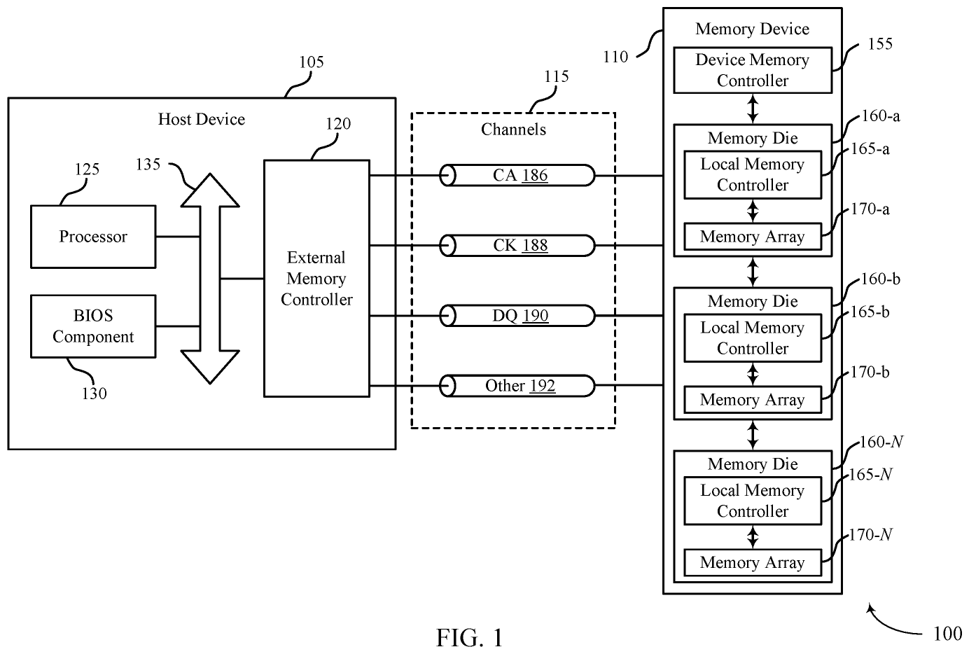

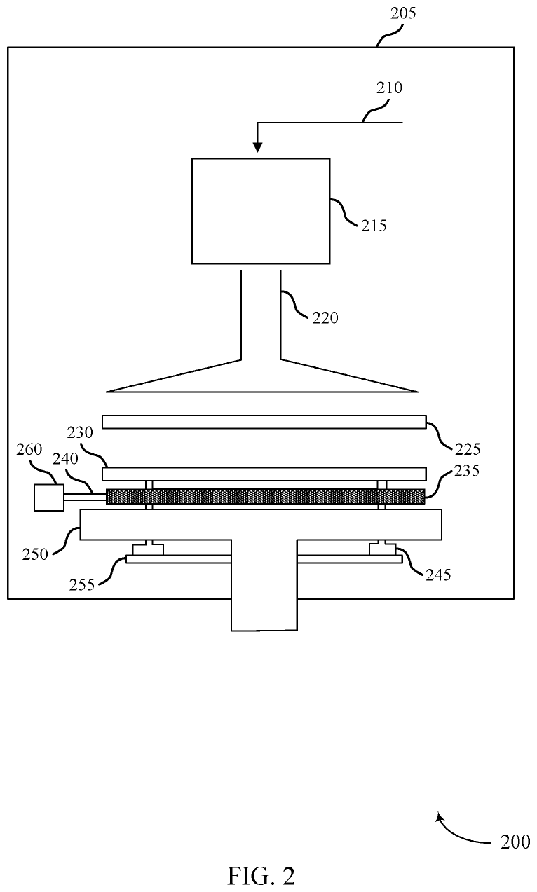

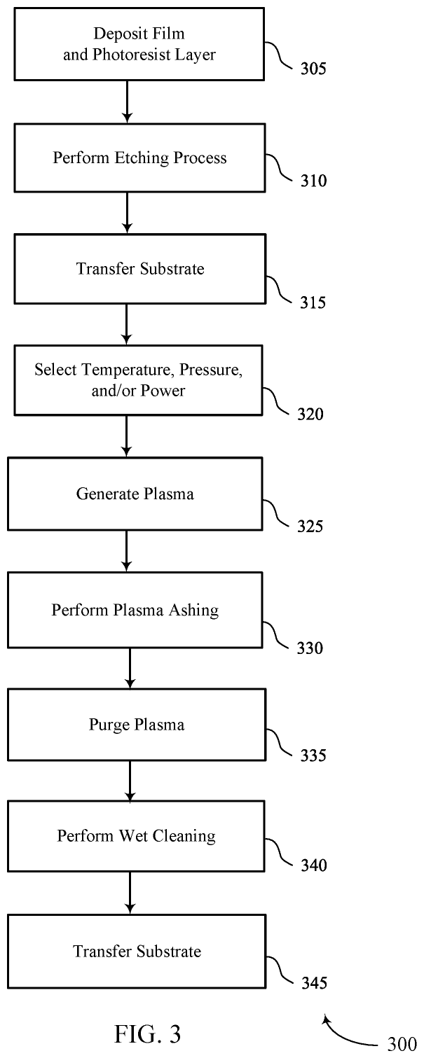

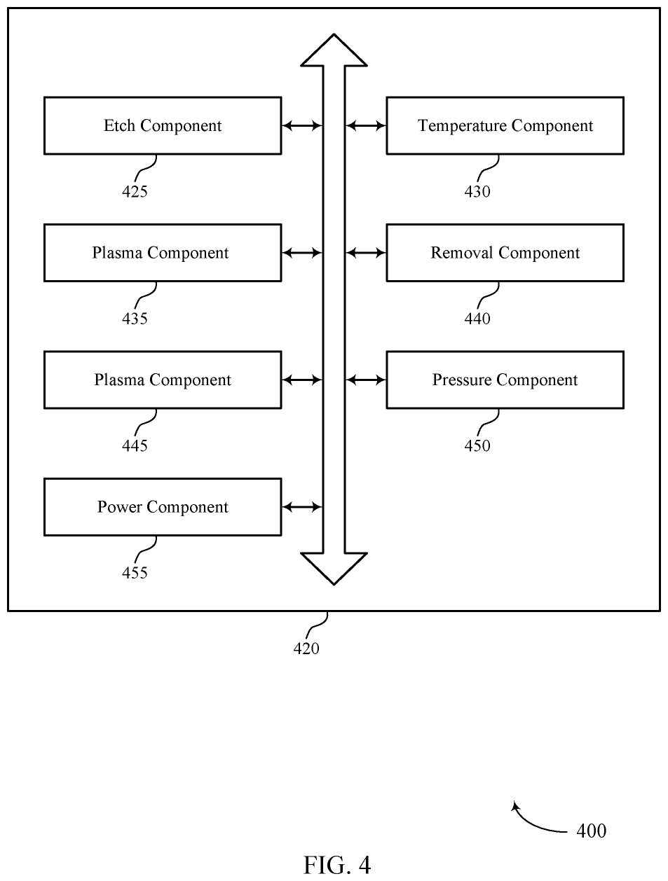

Features of the disclosure are initially described in the context of a system as described with reference to FIG. 1. Features of the disclosure are described in the context a system and process flow as described with reference to FIGS. 2 and 3. These and other features of the disclosure are further illustrated by and described with reference to an apparatus diagram and flowcharts that relate to low parameter plasma ashing techniques as described with reference to FIGS. 4 through 6.

FIG. 1 shows an example of a system 100 that supports low parameter plasma ashing techniques in accordance with examples as disclosed herein. The system 100 may include a host device 105, a memory device 110, and a plurality of channels 115 coupling the host device 105 with the memory device 110. The system 100 may include one or more memory devices 110, but aspects of the one or more memory devices 110 may be described in the context of a single memory device (e.g., memory device 110).

The system 100 may include portions of an electronic device, such as a computing device, a mobile computing device, a wireless device, a graphics processing device, a vehicle, or other systems. For example, the system 100 may illustrate aspects of a computer, a laptop computer, a tablet computer, a smartphone, a cellular phone, a wearable device, an internet-connected device, a vehicle controller, or the like. The memory device 110 may be a component of the system 100 that is operable to store data for one or more other components of the system 100.

Portions of the system 100 may be examples of the host device 105. The host device 105 may be an example of a processor (e.g., circuitry, processing circuitry, a processing component) within a device that uses memory to execute processes, such as within a computing device, a mobile computing device, a wireless device, a graphics processing device, a computer, a laptop computer, a tablet computer, a smartphone, a cellular phone, a wearable device, an internet-connected device, a vehicle controller, a system on a chip (SoC), or some other stationary or portable electronic device, among other examples. In some examples, the host device 105 may refer to the hardware, firmware, software, or any combination thereof that implements the functions of an external memory controller 120. In some examples, the external memory controller 120 may be referred to as a host (e.g., host device 105).

A memory device 110 may be an independent device or a component that is operable to provide physical memory addresses/space that may be used or referenced by the system 100. In some examples, a memory device 110 may be configurable to work with one or more different types of host devices. Signaling between the host device 105 and the memory device 110 may be operable to support one or more of: modulation schemes to modulate the signals, various pin configurations for communicating the signals, various form factors for physical packaging of the host device 105 and the memory device 110, clock signaling and synchronization between the host device 105 and the memory device 110, timing conventions, or other functions.

The memory device 110 may be operable to store data for the components of the host device 105. In some examples, the memory device 110 (e.g., operating as a secondary-type device to the host device 105, operating as a dependent-type device to the host device 105) may respond to and execute commands provided by the host device 105 through the external memory controller 120. Such commands may include one or more of a write command for a write operation, a read command for a read operation, a refresh command for a refresh operation, or other commands.

The host device 105 may include one or more of an external memory controller 120, a processor 125, a basic input/output system (BIOS) component 130, or other components such as one or more peripheral components or one or more input/output controllers. The components of the host device 105 may be coupled with one another using a bus 135.

The processor 125 may be operable to provide functionality (e.g., control functionality) for the system 100 or the host device 105. The processor 125 may be a general-purpose processor, a digital signal processor (DSP), an application-specific integrated circuit (ASIC), a field-programmable gate array (FPGA) or other programmable logic device, discrete gate or transistor logic, discrete hardware components, or any combination of these components. In such examples, the processor 125 may be an example of a central processing unit (CPU), a graphics processing unit (GPU), a general purpose GPU (GPGPU), or an SoC, among other examples. In some examples, the external memory controller 120 may be implemented by or be a part of the processor 125.

The BIOS component 130 may be a software component that includes a BIOS operated as firmware, which may initialize and run various hardware components of the system 100 or the host device 105. The BIOS component 130 may also manage data flow between the processor 125 and the various components of the system 100 or the host device 105. The BIOS component 130 may include instructions (e.g., a program, software) stored in one or more of read-only memory (ROM), flash memory, or other non-volatile memory.

The memory device 110 may include a device memory controller 155 and one or more memory dies 160 (e.g., memory chips) to support a capacity (e.g., a desired capacity, a specified capacity) for data storage. Each memory die 160 (e.g., memory die 160-a, memory die 160-b, memory die 160-N) may include a local memory controller 165 (e.g., local memory controller 165-a, local memory controller 165-b, local memory controller 165-N) and a memory array 170 (e.g., memory array 170-a, memory array 170-b, memory array 170-N). A memory array 170 may be a collection (e.g., one or more grids, one or more banks, one or more tiles, one or more sections) of memory cells, with each memory cell being operable to store one or more bits of data. A memory device 110 including two or more memory dies 160 may be referred to as a multi-die memory or a multi-die package or a multi-chip memory or a multi-chip package.

The device memory controller 155 may include components (e.g., circuitry, logic) operable to control operation of the memory device 110. The device memory controller 155 may include hardware, firmware, or instructions that enable the memory device 110 to perform various operations and may be operable to receive, transmit, or execute commands, data, or control information related to the components of the memory device 110. The device memory controller 155 may be operable to communicate with one or more of the external memory controller 120, the one or more memory dies 160, or the processor 125. In some examples, the device memory controller 155 may control operation of the memory device 110 described herein in conjunction with the local memory controller 165 of the memory die 160.

A local memory controller 165 (e.g., local to a memory die 160) may include components (e.g., circuitry, logic) operable to control operation of the memory die 160. In some examples, a local memory controller 165 may be operable to communicate (e.g., receive or transmit data, commands, or both) with the device memory controller 155. In some examples, a memory device 110 may not include a device memory controller 155, and a local memory controller 165 or the external memory controller 120 may perform various functions described herein. As such, a local memory controller 165 may be operable to communicate with the device memory controller 155, with other local memory controllers 165, or directly with the external memory controller 120, or the processor 125, or any combination thereof. Examples of components that may be included in the device memory controller 155 or the local memory controllers 165 or both may include receivers for receiving signals (e.g., from the external memory controller 120), transmitters for transmitting signals (e.g., to the external memory controller 120), decoders for decoding or demodulating received signals, encoders for encoding or modulating signals to be transmitted, or various other components operable for supporting described operations of the device memory controller 155 or local memory controller 165 or both.

The external memory controller 120 may be operable to enable communication of information (e.g., data, commands, or both) between components of the system 100 (e.g., between components of the host device 105, such as the processor 125, and the memory device 110). The external memory controller 120 may process (e.g., convert, translate) communications exchanged between the components of the host device 105 and the memory device 110. In some examples, the external memory controller 120, or other component of the system 100 or the host device 105, or its functions described herein, may be implemented by the processor 125. For example, the external memory controller 120 may be hardware, firmware, or software, or some combination thereof implemented by the processor 125 or other component of the system 100 or the host device 105. Although the external memory controller 120 is depicted as being external to the memory device 110, in some examples, the external memory controller 120, or its functions described herein, may be implemented by one or more components of a memory device 110 (e.g., a device memory controller 155, a local memory controller 165) or vice versa.

The components of the host device 105 may exchange information with the memory device 110 using one or more channels 115. The channels 115 may be operable to support communications between the external memory controller 120 and the memory device 110. Each channel 115 may be an example of a transmission medium that carries information between the host device 105 and the memory device 110. Each channel 115 may include one or more signal paths (e.g., a transmission medium, a conductor) between terminals associated with the components of the system 100. A signal path may be an example of a conductive path operable to carry a signal. For example, a channel 115 may be associated with a first terminal (e.g., including one or more pins, including one or more pads) at the host device 105 and a second terminal at the memory device 110. A terminal may be an example of a conductive input or output point of a device of the system 100, and a terminal may be operable to act as part of a channel.

Channels 115 (and associated signal paths and terminals) may be dedicated to communicating one or more types of information. For example, the channels 115 may include one or more command and address (CA) channels 186, one or more clock signal (CK) channels 188, one or more data (DQ) channels 190, one or more other channels 192, or any combination thereof. In some examples, signaling may be communicated over the channels 115 using single data rate (SDR) signaling or double data rate (DDR) signaling. In SDR signaling, one modulation symbol (e.g., signal level) of a signal may be registered for each clock cycle (e.g., on a rising or falling edge of a clock signal). In DDR signaling, two modulation symbols (e.g., signal levels) of a signal may be registered for each clock cycle (e.g., on both a rising edge and a falling edge of a clock signal).

Techniques may be described for performing a plasma ashing process using a parameter controlled component, such as a temperature controlled chuck (e.g., clamp), that may be modified by one or more process conditions rather than a static hardware setting. Using low temperature, low pressure, and/or low power may reduce the substrate surface oxidation and minimize the effect on underlying layers. For example, the system 100 (e.g., including at least the device memory controller 155) may effectively strip the photoresist layer, a polymer, and/or a residue at a low temperature, low power and low pressure without affecting or removing underlying layers and preventing the formation of the AN by-product. The system 100 may include portions of an electronic device, such as a computing device, a mobile computing device, a wireless device, or other systems. In such cases, the electronic device of the system 100 may be fabricated by performing the plasma ashing process using the parameter controller component.

For example, the system 100 may perform an etching process on a substrate including the photoresist layer and select one or more parameters, such as at least a temperature of the chuck, that holds the substrate after performing the etching process. In some cases, the device memory controller 155 of the system 100 may select, based on performing the etching process, a temperature of a process chamber, a pressure of the process chamber, and a power of a plasma source located in the process chamber where the etching process is performed such that the temperature, the pressure, and/or the power are below a threshold. The system 100 may generate a plasma that comprises oxygen and apply the plasma to the photoresist layer of the substrate at the selected temperature, selected pressure, and/or selected power to remove the photoresist layer from the substrate. In such cases, the photoresist layer of the substrate may be exposed to the plasma at the selected temperature, selected pressure, and/or selected power to at least partially remove the photoresist layer from the substrate.

In some examples, the system 100 may include the process chamber configured to perform the plasma ashing process; a chuck configured to operate at the selected temperature, selected pressure, and selected power; and the plasma source configured to generate a plasma that comprises oxygen. In some examples, the system 100 may include a baffle plate configured to diffuse the plasma from the plasma source over the chuck at the selected temperature, selected pressure, and selected power. The chuck, the plasma source, and the baffle plate may be included in the process chamber, as described with reference to FIG. 2. In some cases, the system 100 may interact with the process chamber, the chuck, the plasma source, and other components such that the system 100 may transmit instructions to the process chamber to perform the plasma ashing process at the selected temperature, selected pressure, and/or selected power.

FIG. 2 shows an example of a system 200 that supports low parameter plasma ashing techniques in accordance with examples as disclosed herein. The system 200 may include a process chamber 205. The process chamber 205 may include at least a plasma source 215, a baffle plate 225, and a chuck 235. The process chamber 205 may be configured to perform the plasma ashing process using one or more selected parameters, such as at a selected temperature, a selected pressure, a selected power, or any combination thereof.

The plasma ashing process may be performed after the etching process to clean off (e.g., remove) the photoresist layer from the substrate. During the plasma ashing process, a plasma (such as a plasma including some oxygen) may be generated and applied to the photoresist layer. In some cases, applying the oxygen plasma may remove the photoresist layer from the substrate. Removing the photoresist layer may expose a portion of a metal layer (e.g., the substrate, a contact, a STI trench). However, performing the plasma ashing process at high temperatures with an oxygen-based plasma may result in substrate surface oxidation (e.g., oxide growth) on a surface of the substrate. The substrate surface oxidation may remove underlying layers of the substrate and affect subsequent cleaning processes. For example, high temperatures and oxidizing chemistry may increase a thickness of the oxide growth on the surface of the substrate which may cause underlying layer substrate loss, a bridging issue at STI loops, reduced resistance of the underlying metal layers, or any combination thereof. In such cases, minimizing the oxide growth on the surface of the substrate may be desired.

In some cases, for other different techniques performing the plasma ashing process at temperatures about or above 150 degrees Celsius may form an AN by-product that may deposit in the piping of the system 200, thereby integrating into the hardware and reducing the lifetime of the system 200. The AN by-product may an oxidizing agent that may undergo an exothermic reaction with a potential for a safety incident as inadequate segregations of AN precursors from tools or facility systems may lead to AN formation in the confined exhaust system. The plasma ashing processes using reducing chemistries with forming gas or ammonia may form the solid AN by-product in pump exhaust systems. For example, the deposition of the AN by-product in pump exhaust lines may cause safety risks, high parts failure, and increased cost. In such cases, the AN by-product may be a safety risk that uses expensive and time consuming mitigation techniques to reduce or eliminate the AN by-product.

To reduce an amount of oxide growth on the substrate and prevent the formation of the AN by-product, the system 200 may use a dynamically-controllable component, such as a dynamically-controllable chuck 235, as described herein. The chuck 235 may be included in the process chamber 205. The process chamber 205 may be an example of a chamber body. The process chamber 205 may be configured to perform the plasma ashing process. As described herein, the process chamber 205 may house a chuck 235 for cooling to the selected temperature or heating to the selected temperature.

The process chamber 205 may include a gas line 210. The gas line 210 may supply one or more gases, such as the oxygen gas. In some cases, the gas line 210 may supply nitrogen gas, hydrogen gas, one or more other gases, or any combination. The process chamber 205 may include the plasma source 215. The gas line 210 may supply the gas (e.g., oxygen gas) to the plasma source 215. In some cases, the plasma source 215 may be powered by a radiofrequency power source. The plasma source 215 may be configured to generate an oxygen plasma. In order to minimize oxide growth on the substrate, the plasma source 215 may operate at a lower power, as described herein.

The process chamber 205 may include a focus adapter 220. The focus adapter 220 may direct the plasma to the baffle plate 225. The baffle plate 225 may be configured to diffuse the plasma from the plasma source 215 over the chuck 235 at the selected temperature, selected pressure, selected power, or any combination thereof. The baffle plate 225 may be an example of an ion screen, a plate, a mechanical device, or any combination thereof configured to restrain or regulate the flow of the plasma. For example, the baffle plate 225 may include one or more holes configured to diffuse the plasma from the plasma source 215 over the chuck 235.

In some cases, the process chamber 205 may house a substrate 230. The substrate 230 may be an example of a semiconductor wafer, a silicon wafer, a metal material, a silicon oxide material, a material to be etched, or any combination thereof. The substrate 230 may have the photoresist layer. The photoresist layer may include a light-sensitive material of hydrocarbon polymers that may be used to form a patterned coating on top of the substrate 230.

The chuck 235 may be configured to hold the substrate 230 for one or more processes. The chuck 235 may be an example of a clamp, a brace, a lock, a support, or any combination thereof. The chuck 235 may be configured to heat or cool the substrate 230. In such cases, the chuck 235 may be configured to be heated to the selected temperature or cooled to the selected temperature. For example, the chuck 235 may be configured to operate at a selected temperature, selected pressure, selected power, or any combination thereof.

The process chamber 205 may include a temperature component 240. In such cases, the plasma ashing process may be performed with a controllable temperature chuck 235 that may be modifiable by one or more process conditions (e.g., including the temperature component 240) instead of a static setting. The temperature component 240 may be coupled with the chuck 235 and configured to control the temperature of the chuck 235 and/or influence temperature of the process chamber 205. The temperature component 240 may be configured to adjust a temperature of the chuck 235 from a first temperature to the selected temperature (e.g., lower and/or higher). In such cases, the chuck 235 may operate at temperature higher than an ambient temperature of the process chamber 205 by a recipe selectable temperature instead of a manual static hardware setting. In other examples, the chuck 235 may operate at temperature lower than an ambient temperature of the process chamber 205 by the recipe selectable temperature instead of the manual hardware setting. The temperature component 240 may be dialed up or dialed down based on the application (e.g., a type of material of the substrate, a thickness of the substrate, other parameters).

In some cases, the process chamber 205 may include a controller 260. The controller 260 may be coupled with the temperature component 240. In some cases, the controller 260 may be coupled with other components of the process chamber 205 such as the plasma source 215, the chuck 235, the pins 245, the pedestal 250, the lift pin plate 255, or any combination thereof. In some examples, the process chamber 205 may include one or more controllers 260.

The controller 260 may communicate with the chuck 235, via the temperature component 240, to heat or cool the chuck 235 to the selected temperature. In such cases, the controller 260 may transmit instructions to the temperature component 240 to operate the chuck 235 at the selected temperature. For example, the controller 260 may transmit instructions to the chuck 235 to operate at the selected temperature, selected pressure, selected power, or any combination thereof. The controller 260 may be configured to adjust, via the temperature component 240, a temperature of the chuck 235 from a first temperature to the selected temperature (e.g., lower and/or higher) such that the chuck 235 may operate at a temperature higher than an ambient temperature of the process chamber 205 or lower than an ambient temperature of the process chamber 205.

The pins 245 may be configured to adjust the position of the substrate 230 such that the chuck 235 contacts the substrate 230. The pins 245 may lift the substrate 230 off of the chuck 235 for handling procedures such as placing the substrate 230 in the process chamber 205 for the plasma ashing process and removing the substrate 230 from the process chamber 205 after the plasma ashing process is complete. During the plasma ashing process, a bottom surface of the substrate 230 may contact a top surface of the chuck 235. In some cases, the controller 260 may send instructions to the pins 245 to adjust the position of the substrate 230 relative to the chuck 235.

The pedestal 250 may be configured to house the chuck 235. In some cases, the pedestal 250 may be an example of a stage configured to house the chuck 235 on top of the stage. The pins 245 may be coupled with a lift pin plate 255. The lift pin plate 255 may be configured to adjust the position of the substrate 230 relative to the chuck 235 via the pins 245. For example, the controller 260 may communicate with the lift pin plate 255 to adjust the position of the substrate 230.

As described herein, operating the process chamber 205 and the components of the process chamber 205 at a selected temperature, selected pressure, selected power, or any combination thereof may reduce or eliminate an amount of oxide growth on the substrate 230 during the plasma ashing process. The operating parameters (e.g., including the selected temperature, selected pressure, and selected power) may be identified in TABLE 1, which may provide temperature ranges, pressure ranges, and power ranges for operating the process chamber 205 and the components of the process chamber 205 (e.g., including at least the plasma source 215, the chuck 235, or both) distinct from other different techniques. To reduce an amount of oxide growth, temperature, pressure, and power may be dynamically selected based on operating conditions of the process chamber 205, a type of material of the substrate 230, other parameters, or any combination thereof.

TABLE 1

| Parameter | Range 1 | | Range 2 | | Range 3 | |
|---|---|---|---|---|---|---|
| Tempera- | <150° | C. | 10-100° | C. | 10-50° | C. |
| ture | | | | | | |
| Pressure | <1000 | mTorr | 100-500 | mTorr | 100-300 | mTorr |
| Power | <3000 | W | 1000-2000 | W | 1200-1500 | W |

In some examples, the selected temperature may be less than 150 degrees Celsius (e.g., Range 1). In some cases, the selected temperature may include a temperature between 10 degrees Celsius and 100 degrees Celsius (e.g., Range 2). In some cases, the selected temperature may include a temperature between 10 degrees Celsius and 50 degrees Celsius (e.g., Range 3). In some examples, the chuck 235 may operate at the selected temperature of less than 150 degrees Celsius, the selected temperature between 10 degrees Celsius and 100 degrees Celsius, or the selected temperature between 10 degrees Celsius and 50 degrees Celsius.

The process chamber 205 may operate at the selected temperature of less than 150 degrees Celsius, the selected temperature between 10 degrees Celsius and 100 degrees Celsius, or the selected temperature between 10 degrees Celsius and 50 degrees Celsius. In other examples, the plasma source 215 may operate at the selected temperature of less than 150 degrees Celsius, the selected temperature between 10 degrees Celsius and 100 degrees Celsius, or the selected temperature between 10 degrees Celsius and 50 degrees Celsius, thereby generating a plasma at the selected temperature. In some cases, as the temperature increases, an amount of oxide growth may increase. In such cases, the process chamber 205, the plasma source 215, and the chuck 235 may operate at the selected temperature between 10 degrees Celsius and 50 degrees Celsius rather than the selected temperature between 10 degrees Celsius and 100 degrees Celsius or selected temperature less than 150 degrees Celsius to reduce an amount of oxide growth. In some cases, operating the process chamber 205, the plasma source 215, and the chuck 235 at lower temperatures may mitigate oxidation (e.g., the oxide growth). In some examples, operating at lower temperatures may prevent corrosion of the substrate, prevent the formation of the AN by-product, and prevent a bridging defect at the STI trench. In such cases, the process chamber 205, the plasma source 215, and the chuck 235 may operate at the selected temperature between 10 degrees Celsius and 100 degrees Celsius rather than the selected temperature less than 150 degrees Celsius to reduce an amount of oxide growth.

The lower temperatures may mitigate oxidation (e.g., the oxide growth). However, the plasma ashing process may be less efficient at lower temperatures. In such cases, the optimum operating temperature may balance oxidation and strip rate of the plasma ashing process. For example, the process chamber 205, the plasma source 215, and the chuck 235 may operate at the selected temperature less than 150 degrees Celsius to perform the plasma ashing process more efficiently than operating at the selected temperature between 10 degrees Celsius and 50 degrees Celsius or the selected temperature between 10 degrees Celsius and 100 degrees Celsius. In other examples, the process chamber 205, the plasma source 215, and the chuck 235 may operate at the selected temperature between 10 degrees Celsius and 100 degrees Celsius to perform the plasma ashing process more efficiently than operating at the selected temperature between 10 degrees Celsius and 50 degrees Celsius but less efficiently than operating at the selected temperature less than 150 degrees Celsius. In such cases, operating at the selected temperature between 10 degrees Celsius and 100 degrees Celsius may have a lower oxidation rate than operating at the selected temperature less than 150 degrees Celsius but may have a higher oxidation rate than operating at the selected temperature between 10 degrees Celsius and 50 degrees Celsius.

In some cases, the selected pressure may be less than 1000 millitorr (e.g., Range 1). In some examples, the selected pressure may be between 100 millitorr and 500 millitorr (e.g., Range 2). In other examples, the selected pressure may include a pressure between 100 millitorr and 300 millitorr (e.g., Range 3). In some examples, the chuck 235, the process chamber 205, and the plasma source 215 may operate at the selected pressure of a pressure less than 1000 millitorr, a pressure between 100 millitorr and 500 millitorr, or a pressure between 100 millitorr and 300 millitorr. In some cases, operating the process chamber 205, the plasma source 215, and the chuck 235 at lower pressures may reduce an amount of oxide growth, among other benefits. In such cases, the process chamber 205, the plasma source 215, and the chuck 235 may operate at the selected pressure between 100 millitorr and 300 millitorr rather than the selected pressure between 100 millitorr and 500 millitorr or selected pressure of a pressure less than 1000 millitorr to reduce an amount of oxide growth. Operating at lower pressures may result in less oxidation on metals and polysilicon due to an absence of reactants and collision that allow oxidation to occur.

The selected pressure may affect the charged potential distribution for the plasma ashing process. For example, the selected pressure may define properties of the plasma source 215 (e.g., including the plasma) such as a plasma ionization rate, an electron temperature, an amount of plasma loss through various collision mechanisms, and the like. The selected pressure may also affect a strip rate, an amount of plasma damage, and a rate of oxidation, as described herein. For example, operating at lower pressures may reduce a charge-up potential collision to remove the photoresist layer while also preventing surface damage. In such cases, the process chamber 205, the plasma source 215, and the chuck 235 may operate at the selected pressure between 100 millitorr and 300 millitorr rather than the selected pressure between 100 millitorr and 500 millitorr or selected pressure of a pressure less than 1000 millitorr to remove the photoresist layer while preventing surface damage.

In some cases, the type of plasma source 215 may determine the operating pressure. For example, a plasma source 215 using inductively coupled plasma (ICP) may operate more efficiently at a lower selected pressure (e.g., less than or equal to 100 millitorr). In such cases, the plasma source 215 using ICP may operate more efficiently at the selected pressure between 100 millitorr and 300 millitorr rather than the selected pressure between 100 millitorr and 500 millitorr or the selected pressure less than 1000 millitorr. A plasma source 215 using capacitively coupled plasma (CCP) may operate more efficiently at a higher selected pressure (e.g., greater than 100 millitorr). In such cases, the plasma source 215 using CCP may operate more efficiently at the selected pressure less than 1000 millitorr rather than the selected pressure between 100 millitorr and 300 millitorr or the selected pressure between 100 millitorr and 500 millitorr. A plasma source 215 using microwave plasma may operate more efficiently at a selected pressure of 1000 millitorr. For example, the plasma source 215 using microwave plasma may operate more efficiently at the selected pressure less than 1000 millitorr rather than the selected pressure between 100 millitorr and 300 millitorr or the selected pressure between 100 millitorr and 500 millitorr.

In some examples, the selected power may be less than 3000 watts (e.g., Range 1). The selected power may include a power between 1000 watts and 2000 watts (e.g., Range 2). In some cases, the selected power may include a power between 1200 watts and 1500 watts (e.g., Range 3). In some examples, the chuck 235, the process chamber 205, and the plasma source 215 may operate at the selected power of less than 3000 watts, between 1000 watts and 2000 watts, or between 1200 watts and 1500 watts. In some cases, the selected power may accommodate the selected temperature in order to mitigate oxide growth. For example, as the power increases, the oxide growth may increase. In such cases, the process chamber 205, the plasma source 215, and the chuck 235 may operate at the selected power between 1200 watts and 1500 watts rather than the selected power between 1000 watts and 2000 watts or the selected power less than 3000 watts to reduce an amount of oxide growth. In some examples, operating the process chamber 205, the plasma source 215, and the chuck 235 at a lower power may minimize amounts of substrate surface oxidation, among other benefits.

The electromagnetic radiation emitted from the plasma source 215 may energize the feed gas from the gas line 210 into a plasma. The downstream processing may enable ions in the plasma to sufficiently relax such that the bulk of the species interacting with the surface of the substrate 230 may be highly reactive neutral radicals (e.g., high neutral density and low ion density). The radicals may react with the organic material on the surface of the substrate 230 and are converted to volatile byproducts which are pumped away from the reactor (e.g., the process chamber 205). The ashing rate may be an example of a rate at which the volatile byproducts are pumped away from the reactor. An increase in plasma power may increase the ashing rate and subsequently impact the oxidation rate. In such cases, a lower power may be selected to reduce the oxide growth.

For example, the process chamber 205, the plasma source 215, and the chuck 235 may operate at the selected power between 1200 watts and 1500 watts rather than the selected power between 1000 watts and 2000 watts or the selected power less than 3000 watts to decrease the ashing rate. In other examples, the process chamber 205, the plasma source 215, and the chuck 235 may operate at the selected power between 1000 watts and 2000 watts to have a lower ashing rate than operating at the selected power less than 3000 watts but a higher ashing rate than operating at the selected power between 1200 watts and 1500 watts. In such cases, operating at the selected power between 1000 watts and 2000 watts may have a lower oxidation rate than operating at the selected power less than 3000 watts but may have a higher oxidation rate than operating at the selected power between 1200 watts and 1500 watts.

In some cases, the system 200 (e.g., including at least the process chamber 205, the plasma source 215, and the chuck 235) may operate at the selected temperature between 10 degrees Celsius and 50 degrees Celsius, selected pressure between 100 millitorr and 300 millitorr, and selected power between 1200 watts and 1500 watts to minimize the substrate surface oxidation and the formation of the AN by-product. In some examples, the system 200 may operate at the selected temperature between 10 degrees Celsius and 50 degrees Celsius and the selected pressure between 100 millitorr and 300 millitorr while the selected power may vary to decrease the oxidation rate. For example, the system 200 may operate at the selected temperature between 10 degrees Celsius and 100 degrees Celsius and the selected pressure between 100 millitorr and 500 millitorr to have a higher oxidation rate than operating at the selected temperature between 10 degrees Celsius and 50 degrees Celsius and the selected pressure between 100 millitorr and 300 millitorr but a lower oxidation rate than operating at the selected temperature less than 150 degrees Celsius and the selected pressure less than 1000 millitorr.

In other examples, the system 200 may operate at the selected temperature between 10 degrees Celsius and 50 degrees Celsius and the selected power between 1200 watts and 1500 watts while the selected pressure may vary to decrease the oxidation rate. For example, the system 200 may operate at the selected temperature between 10 degrees Celsius and 100 degrees Celsius and the selected power between 1000 watts and 2000 watts to perform the plasma ashing process more efficiently than operating at the selected temperature between 10 degrees Celsius and 50 degrees Celsius and the selected power between 1200 watts and 1500 watts but less efficiently than operating at the selected temperature less than 150 degrees Celsius and the selected power less than 3000 watts.

As described herein, the system 200 may support low parameter plasma ashing techniques, as described with reference to FIG. 3. In some examples, the system 200 including the process chamber 205, the plasma source 215, and the chuck 235 may perform the etching process and the plasma ashing process to fabricate an electronic device, as further described with reference to FIG. 3.

FIG. 3 shows an example of a process flow 300 that supports low parameter plasma ashing techniques in accordance with examples as disclosed herein. The operations of process flow 300 may be implemented by a system or its components as described herein. Alternative examples of the following may be implemented, where some steps are performed in a different order or not at all. Some steps may additionally include additional features not mentioned below. The process flow 300 illustrates techniques where plasma ashing may be performed at a selected temperature, selected pressure, selected power, or any combination thereof to minimize an amount of substrate surface oxidation.

Aspects of the process flow 300 may be implemented by components of FIGS. 1 and 2, among other components. Additionally or alternatively, aspects of the process flow 300 may be implemented as instructions stored in memory (e.g., firmware stored in a memory coupled with the system 100 and/or system 200). For example, the instructions, if executed by the controller 155 (e.g., the device memory controller 155), may cause the system to perform the operations of the process flow 300.

At 305, the photoresist layer of the substrate may be formed. The photoresist layer of the substrate may be formed prior to performing an etching process. The process chamber 205, as described with reference to FIG. 2, may form the photoresist layer of the substrate. For example, a film (e.g., the substate) may be deposited on a base layer. The substrate may be an example of a material to be etched such as a silicon wafer. The photoresist layer may be formed over the substrate after the substrate is deposited. In some cases, the method may include exposing the photoresist layer to an ultraviolet (UV) light such that a portion of the photoresist layer may be removed and a portion of the substrate below the photoresist layer is uncovered. For example, the photoresist layer may cover portions of the substrate while the portion of the photoresist layer that is removed may expose the portion of the substrate (e.g., remain uncovered).

At 310, the method may include performing the etching process. During the etching process, a portion of the substrate may be removed such that a portion of the base layer may be exposed. In some cases, the method may include determining an operating condition of the process chamber, a type of material of the substrate, or both based on performing the etching process. For example, the controller 260, as described with reference to FIG. 2, may determine the operating condition of the process chamber the type of material of the substrate, or both.

At 315, the substrate may be transferred, for example into or within, a chamber after the etching process is complete. A component of the process chamber 205, as described with reference to FIG. 2, transfer the substrate. In some cases, the substrate may be transferred into the chamber before the etching process is performed. The chamber may be an example of a process chamber, an etching chamber, a vacuum chamber, or any combination thereof. At 315, the substrate may be placed on a chuck.

At 320, a temperature, pressure, power, or any combination thereof may be selected. For example, the method may include selecting, based on performing the etching process, a temperature of a process chamber, a pressure of the process chamber, a power of a plasma source, or any combination thereof. In some examples, the controller 260, as described with reference to FIG. 2, may select the temperature, the pressure, the power, or any combination thereof. For example, the method may include selecting the power of the plasma source for applying the plasma to the photoresist layer after performing the etching process. The selected power may include a power between 1200 watts and 1500 watts, a power between 1000 watts and 2000 watts, or a power less than 3000 watts. In other examples, the method may include selecting a temperature of the plasma applied to the photoresist layer. The selected temperature may include a temperature between 10 degrees Celsius and 50 degrees Celsius, a temperature between 10 degrees Celsius and 100 degrees Celsius, or a temperature less than 150 degrees Celsius. The selected pressure may include a pressure between 100 millitorr and 300 millitorr, a pressure between 100 millitorr and 500 millitorr, or a pressure less than 1000 millitorr.

In some examples, the method may include selecting a temperature of the chuck for holding the substrate after performing the etching process. The chuck may be heated to a temperature higher than an ambient temperature of the process chamber. For example, the chuck may be configured to operate at a temperature higher than the ambient temperature of the process chamber housing the chuck. In such cases, the chuck may be configured to be heated to the selected temperature where the selected temperature is higher than the ambient temperature of the process chamber. In some cases, the substrate held by the chuck may be preheated prior to the plasma ashing process.

In other examples, the chuck may be cooled to a temperature lower than the ambient temperature of the process chamber. In such cases, the chuck may be configured to be cooled to the selected temperature where the selected temperature is lower than the ambient temperature of the process chamber. For example, the chuck may be configured to operate at a temperature lower than the ambient temperature of the process chamber housing the chuck. In such cases, the temperature of the chuck is less than the ambient temperature, and the substrate held by the chuck may be precooled prior to and/or as part of the plasma ashing process. In some cases, precooling the chuck may minimize oxide growth and enable process improvements by reducing substate loss, improving contact resistance, and reducing downstream processes and contamination from peeling defects, among other benefits.

In some cases, the method may include adjusting the selected temperature, selected pressure, selected power, or any combination thereof in response to selecting the temperature, pressure, power, or any combination thereof. The controller 260, as described with reference to FIG. 2, may adjust the selected temperature, selected pressure, selected power, or any combination thereof. For example, the method may include adjusting the selected temperature from a first temperature to a second temperature in response to determining the operating condition of the process chamber, the type of material of the substrate, or both. In some cases, the selected pressure may be adjusted from a first pressure to a second pressure in response to determining the operating condition of the process chamber, the type of material of the substrate, or both. In some examples, the selected power may be adjusted from a first power to a second power in response to determining the operating condition of the process chamber, an operation condition of the plasma source, the type of material of the substrate, or any combination thereof.

At 325, the plasma may be generated at the plasma source. The plasma may be an example of an oxygen plasma. In some cases, the plasma may be generated based on selecting the temperature of the chuck. In some examples, the plasma may be generated based on selecting the temperature of the process chamber, the pressure of the process chamber, the power of the plasma source, or any combination thereof. The oxygen gas source may be turned on and then the plasma may be generated at the plasma source by combing the plasma and the oxygen gas. In some cases, the plasma source 215, as described with reference to FIG. 2, may generate the plasma.

At 330, the plasma ashing process may be performed. In some cases, the process chamber 205, as described with reference to FIG. 2, may perform the plasma ashing process. After the etching process is complete, the photoresist layer may be at least partially removed (e.g., stripped) from the surface of the substrate by performing the plasma ashing process. Plasma ashing process may be an example of a dry strip process to burn organic films, compounds, or other materials off the surface of the substrate. In some cases, plasma ashing process may cause substrate surface oxidation (e.g., oxide growth) due to the high temperatures of the oxidizing chemistry which may cause underlying layer substrate loss. In such cases, performing the plasma ashing process at lower temperatures may be desired to minimize the amount of substrate surface oxidation.

For example, the photoresist layer of the substate may be exposed to the plasma at the selected temperature, selected pressure, selected power, or any combination thereof to at least partially remove the photoresist layer from the substrate. In such cases, the plasma may be applied to the photoresist layer at the selected temperature, selected pressure, selected power, or any combination thereof. In some cases, the photoresist layer may be fully removed from the substrate based on applying the plasma to the photoresist layer and exposing the photoresist layer to the plasma. The plasma may be oxidized on the surface of the photoresist layer such that a portion of the photoresist layer may be removed. The plasma may be applied after adjusting at least one of the selected temperature, the selected pressure, or the selected power.

At 335, the plasma from the process chamber may be removed. For example, after the plasma ashing process is complete, the plasma may be purged from the process chamber. In such cases, the plasma may be removed from the process chamber after exposing the photoresist layer of the substrate to the plasma at the selected temperature, selected pressure, selected power, or any combination thereof. The process chamber 205, as described with reference to FIG. 2, may purge the plasma.

At 340, a wet cleaning process may be performed. For example, the method may include performing the wet cleaning process after completing the plasma ashing process and purging the plasma from the plasma chamber. In some examples, the process chamber 205, as described with reference to FIG. 2 may perform the wet cleaning process. At 345, the substrate may be transferred, for example out of or within, the process chamber. In such cases, the substrate may be transferred out of the process after the wet cleaning process is performed. A component of the process chamber 205, as described with reference to FIG. 2, transfer the substrate. The substrate may undergo an inspection after the substrate is removed from the process chamber, and the photoresist layer is at least partially removed.

In some cases, performing the plasma ashing process at the selected temperature, selected pressure, selected power, or any combination thereof may improve the safety of the system and increase the technical performance of the system. For example, operating the components of the system at the selected temperature, selected pressure, selected power, or any combination thereof may improve the lifetime of the system by eliminating a metal corrosion defect source, preventing the formation of the AN by-product, and preventing a bridging defect at the STI. In some cases, operating the chuck at the selected temperature may enable process improvements by reducing substate loss, improving contact resistance, and reducing downstream processes and contamination from peeling defects, among other benefits.

FIG. 4 shows a block diagram 400 of a system 420 that supports low parameter plasma ashing techniques in accordance with examples as disclosed herein. The system 420 may be an example of aspects of a System as described with reference to FIGS. 1 through 3. The system 420, or various components thereof, may be an example of means for performing various aspects of low parameter plasma ashing techniques as described herein. For example, the system 420 may include an etch component 425, a temperature component 430, a plasma component 435, a removal component 440, a plasma component 445, a pressure component 450, a power component 455, or any combination thereof. Each of these components may communicate, directly or indirectly, with one another (e.g., via one or more buses).

The etch component 425 may be configured as or otherwise support a means (e.g., a process chamber) for performing an etching process on a substrate including a photoresist layer. The temperature component 430 may be configured as or otherwise support a means (e.g., a controller) for selecting at least a temperature of a clamp for holding the substrate based at least in part on performing the etching process. The plasma component 435 may be configured as or otherwise support a means (e.g., a plasma source) for generating a plasma that includes oxygen based at least in part on selecting the temperature of the clamp for holding the substrate. The removal component 440 may be configured as or otherwise support a means (e.g., a chuck) for exposing the photoresist layer of the substrate to the plasma at the selected temperature to at least partially remove the photoresist layer from the substrate.

In some examples, the pressure component 450 may be configured as or otherwise support a means (e.g. the controller) for selecting a pressure of a process chamber for housing the clamp based at least in part on performing the etching process, where exposing the photoresist layer of the substrate to the plasma includes exposing the photoresist layer of the substrate to the plasma at the selected pressure to at least partially remove the photoresist layer from the substrate.

In some examples, the selected pressure includes a pressure between 100 millitorr and 300 millitorr.

In some examples, the power component 455 may be configured as or otherwise support a means (e.g. the controller) for selecting a power of a plasma source for applying the plasma to the photoresist layer of the substrate based at least in part on performing the etching process, where exposing the photoresist layer of the substrate to the plasma includes exposing the photoresist layer of the substrate to the plasma at the selected power to at least partially remove the photoresist layer from the substrate.

In some examples, the selected power includes a power between 1200 watts and 1500 watts.

In some examples, the selected temperature includes a temperature between 10 degrees Celsius and 50 degrees Celsius.

In some examples, the clamp includes a chuck, a brace, a lock, a support, or any combination thereof.

In some examples, the temperature component 430 may be configured as or otherwise support a means (e.g., the controller) for adjusting the selected temperature from a first temperature to a second temperature based at least in part on determining an operating condition of a process chamber for housing the clamp, a type of material of the substrate, or both.

In some examples, the etch component 425 may be configured as or otherwise support a means (e.g., the process chamber) for forming the photoresist layer of the substrate prior to performing the etching process.

In some examples, the removal component 440 may be configured as or otherwise support a means (e.g., the process chamber) for removing the plasma from a process chamber based at least in part on exposing the photoresist layer of the substrate to the plasma at the selected temperature.

In some examples, the clamp is configured to be heated to the selected temperature or cooled to the selected temperature.

In some examples, the clamp is configured to be cooled to the selected temperature.

In some examples, the clamp is configured to operate at a temperature lower than an ambient temperature of a process chamber housing the clamp.

In some examples, the etch component 425 may be configured as or otherwise support a means (e.g., the process chamber) for performing an etching process on a substrate including a photoresist layer. In some examples, the temperature component 430 may be configured as or otherwise support a means (e.g., the controller) for selecting, based at least in part on performing the etching process, a temperature of a process chamber, a pressure of the process chamber, and a power of a plasma source located in the process chamber where the etching process is performed. The plasma component 445 may be configured as or otherwise support a means (e.g., the plasma source) for applying a plasma to the photoresist layer of the substrate at the selected temperature, pressure, and power to remove the photoresist layer from the substrate.

In some examples, the etch component 425 may be configured as or otherwise support a means (e.g., the controller) for determining an operating condition of the process chamber, a type of material of the substrate, or both based at least in part on performing the etching process. In some examples, the temperature component 430 may be configured as or otherwise support a means (e.g. the controller) for adjusting at least one of the selected temperature, pressure, or power from a first value to a value based at least in part on determining the operating condition of the process chamber, the type of material of the substrate, or both, where applying the plasma is based at least in part on adjusting at least one of the selected temperature, the selected pressure, or the selected power.

In some examples, the process chamber is configured to operate at a temperature lower than an ambient temperature of the process chamber.

In some examples, the process chamber houses a clamp for cooling to the selected temperature.

In some examples, the selected temperature includes a temperature between 10 degrees Celsius and 100 degrees Celsius.

In some examples, the selected pressure includes a pressure between 100 millitorr and 500 millitorr.

In some examples, the selected power includes a power between 1000 watts and 2000 watts.

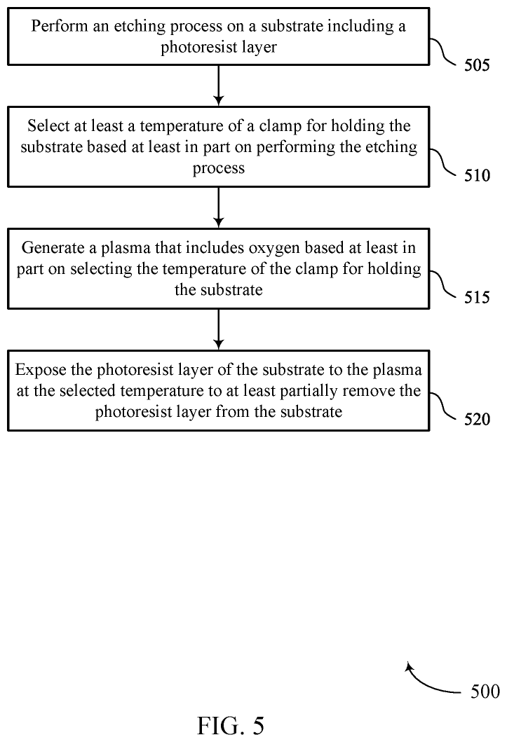

FIG. 5 shows a flowchart illustrating a method 500 that supports low parameter plasma ashing techniques in accordance with examples as disclosed herein. The operations of method 500 may be implemented by a System or its components as described herein. For example, the operations of method 500 may be performed by a System as described with reference to FIGS. 1 through 4. In some examples, a System may execute a set of instructions to control the functional elements of the device to perform the described functions. Additionally, or alternatively, the System may perform aspects of the described functions using special-purpose hardware.

At 505, the method may include performing an etching process on a substrate including a photoresist layer. The operations of 505 may be performed in accordance with examples as disclosed herein. In some examples, aspects of the operations of 505 may be performed by an etch component 425 as described with reference to FIG. 4.

At 510, the method may include selecting at least a temperature of a clamp for holding the substrate based at least in part on performing the etching process. The operations of 510 may be performed in accordance with examples as disclosed herein. In some examples, aspects of the operations of 510 may be performed by a temperature component 430 as described with reference to FIG. 4.

At 515, the method may include generating a plasma that includes oxygen based at least in part on selecting the temperature of the clamp for holding the substrate. The operations of 515 may be performed in accordance with examples as disclosed herein. In some examples, aspects of the operations of 515 may be performed by a plasma component 435 as described with reference to FIG. 4.

At 520, the method may include exposing the photoresist layer of the substrate to the plasma at the selected temperature to at least partially remove the photoresist layer from the substrate. The operations of 520 may be performed in accordance with examples as disclosed herein. In some examples, aspects of the operations of 520 may be performed by a removal component 440 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for performing an etching process on a substrate including a photoresist layer; selecting at least a temperature of a clamp for holding the substrate based at least in part on performing the etching process; generating a plasma that includes oxygen based at least in part on selecting the temperature of the clamp for holding the substrate; and exposing the photoresist layer of the substrate to the plasma at the selected temperature to at least partially remove the photoresist layer from the substrate.

Aspect 2: The method, apparatus, or non-transitory computer-readable medium of aspect 1, further including operations, features, circuitry, logic, means, or instructions, or any combination thereof for selecting a pressure of a process chamber for housing the clamp based at least in part on performing the etching process, where exposing the photoresist layer of the substrate to the plasma includes exposing the photoresist layer of the substrate to the plasma at the selected pressure to at least partially remove the photoresist layer from the substrate.

Aspect 3: The method, apparatus, or non-transitory computer-readable medium of aspect 2, where the selected pressure includes a pressure between 100 millitorr and 300 millitorr.

Aspect 4: The method, apparatus, or non-transitory computer-readable medium of any of aspects 1 through 3, further including operations, features, circuitry, logic, means, or instructions, or any combination thereof for selecting a power of a plasma source for applying the plasma to the photoresist layer of the substrate based at least in part on performing the etching process, where exposing the photoresist layer of the substrate to the plasma includes exposing the photoresist layer of the substrate to the plasma at the selected power to at least partially remove the photoresist layer from the substrate.

Aspect 5: The method, apparatus, or non-transitory computer-readable medium of aspect 4, where the selected power includes a power between 1200 watts and 1500 watts.

Aspect 6: The method, apparatus, or non-transitory computer-readable medium of any of aspects 1 through 5, where the selected temperature includes a temperature between 10 degrees Celsius and 50 degrees Celsius.

Aspect 7: The method, apparatus, or non-transitory computer-readable medium of any of aspects 1 through 6, where the clamp includes a chuck, a brace, a lock, a support, or any combination thereof.

Aspect 8: The method, apparatus, or non-transitory computer-readable medium of any of aspects 1 through 7, further including operations, features, circuitry, logic, means, or instructions, or any combination thereof for adjusting the selected temperature from a first temperature to a second temperature based at least in part on determining an operating condition of a process chamber for housing the clamp, a type of material of the substrate, or both.

Aspect 9: The method, apparatus, or non-transitory computer-readable medium of any of aspects 1 through 8, further including operations, features, circuitry, logic, means, or instructions, or any combination thereof for forming the photoresist layer of the substrate prior to performing the etching process.

Aspect 10: The method, apparatus, or non-transitory computer-readable medium of any of aspects 1 through 9, further including operations, features, circuitry, logic, means, or instructions, or any combination thereof for removing the plasma from a process chamber based at least in part on exposing the photoresist layer of the substrate to the plasma at the selected temperature.

Aspect 11: The method, apparatus, or non-transitory computer-readable medium of any of aspects 1 through 10, where the clamp is configured to be heated to the selected temperature or cooled to the selected temperature.

Aspect 12: The method, apparatus, or non-transitory computer-readable medium of any of aspects 1 through 11, where the clamp is configured to be cooled to the selected temperature.

Aspect 13: The method, apparatus, or non-transitory computer-readable medium of any of aspects 1 through 12, where the clamp is configured to operate at a temperature lower than an ambient temperature of a process chamber housing the clamp.

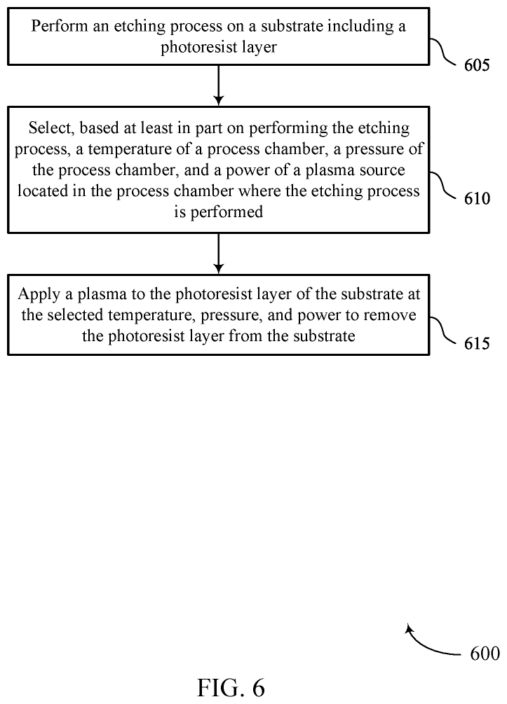

FIG. 6 shows a flowchart illustrating a method 600 that supports low parameter plasma ashing techniques in accordance with examples as disclosed herein. The operations of method 600 may be implemented by a System or its components as described herein. For example, the operations of method 600 may be performed by a System as described with reference to FIGS. 1 through 4. In some examples, a System may execute a set of instructions to control the functional elements of the device to perform the described functions. Additionally, or alternatively, the System may perform aspects of the described functions using special-purpose hardware.

At 605, the method may include performing an etching process on a substrate including a photoresist layer. The operations of 605 may be performed in accordance with examples as disclosed herein. In some examples, aspects of the operations of 605 may be performed by an etch component 425 as described with reference to FIG. 4.

At 610, the method may include selecting, based at least in part on performing the etching process, a temperature of a process chamber, a pressure of the process chamber, and a power of a plasma source located in the process chamber where the etching process is performed. The operations of 610 may be performed in accordance with examples as disclosed herein. In some examples, aspects of the operations of 610 may be performed by a temperature component 430 as described with reference to FIG. 4.

At 615, the method may include applying a plasma to the photoresist layer of the substrate at the selected temperature, pressure, and power to remove the photoresist layer from the substrate. The operations of 615 may be performed in accordance with examples as disclosed herein. In some examples, aspects of the operations of 615 may be performed by a plasma component 445 as described with reference to FIG. 4.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 14: A method, apparatus, or non-transitory computer-readable medium including operations, features, circuitry, logic, means, or instructions, or any combination thereof for performing an etching process on a substrate including a photoresist layer; selecting, based at least in part on performing the etching process, a temperature of a process chamber, a pressure of the process chamber, and a power of a plasma source located in the process chamber where the etching process is performed; and applying a plasma to the photoresist layer of the substrate at the selected temperature, pressure, and power to remove the photoresist layer from the substrate.

Aspect 15: The method, apparatus, or non-transitory computer-readable medium of aspect 14, further including operations, features, circuitry, logic, means, or instructions, or any combination thereof for determining an operating condition of the process chamber, a type of material of the substrate, or both based at least in part on performing the etching process and adjusting at least one of the selected temperature, pressure, or power from a first value to a value based at least in part on determining the operating condition of the process chamber, the type of material of the substrate, or both, where applying the plasma is based at least in part on adjusting at least one of the selected temperature, the selected pressure, or the selected power.

Aspect 16: The method, apparatus, or non-transitory computer-readable medium of any of aspects 14 through 15, where the process chamber is configured to operate at a temperature lower than an ambient temperature of the process chamber.

Aspect 17: The method, apparatus, or non-transitory computer-readable medium of any of aspects 14 through 16, where the process chamber houses a clamp for cooling to the selected temperature.

Aspect 18: The method, apparatus, or non-transitory computer-readable medium of any of aspects 14 through 17, where the selected temperature includes a temperature between 10 degrees Celsius and 100 degrees Celsius.

Aspect 19: The method, apparatus, or non-transitory computer-readable medium of any of aspects 14 through 18, where the selected pressure includes a pressure between 100 millitorr and 500 millitorr.

Aspect 20: The method, apparatus, or non-transitory computer-readable medium of any of aspects 14 through 19, where the selected power includes a power between 1000 watts and 2000 watts.

It should be noted that the methods described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 21: An apparatus, including: a process chamber configured to perform a plasma ashing process, where the process chamber includes; a clamp configured to operate at a selected temperature, pressure, and power; a plasma source configured to generate a plasma that includes oxygen; and a baffle plate configure to diffuse the plasma from the plasma source over the clamp at the selected temperature, selected pressure, and selected power.

Aspect 22: The apparatus of aspect 21, where the process chamber further includes: a temperature component coupled with the clamp and configured to adjust a temperature of the clamp from a first temperature to the selected temperature.

Aspect 23: The apparatus of aspect 22, where the clamp is configured to operate at a temperature between 10 degrees Celsius and 50 degrees Celsius.

Aspect 24: The apparatus of any of aspects 22 through 23, where the clamp is configured to operate at a temperature lower than an ambient temperature of the process chamber.

Aspect 25: The apparatus of any of aspects 21 through 24, where the process chamber is configured to operate at a temperature less than 150 degrees Celsius.

Aspect 26: The apparatus of any of aspects 21 through 25, where the process chamber is configured to operate at a pressure less than 1000 millitorr.

Aspect 27: The apparatus of any of aspects 21 through 26, where the plasma source is configured to operate at a power less than 3000 watts.

Aspect 28: The apparatus of any of aspects 21 through 27, where the process chamber further includes: a stage configured to house the clamp, where the clamp includes a chuck, a brace, a lock, a support, or any combination thereof.

Aspect 29: The apparatus of any of aspects 21 through 28, where the plasma source is configured to output the plasma at a temperature between 10 degrees Celsius and 50 degrees Celsius.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

The terms “layer” and “level” used herein refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component (e.g., a transistor) discussed herein may represent a field-effect transistor (FET), and may comprise a three-terminal component including a source (e.g., a source terminal), a drain (e.g., a drain terminal), and a gate (e.g., a gate terminal). The terminals may be connected to other electronic components through conductive materials (e.g., metals, alloys). The source and drain may be conductive, and may comprise a doped (e.g., heavily-doped, degenerate) semiconductor region. The source and drain may be separated by a doped (e.g., lightly-doped) semiconductor region or channel. If the channel is n-type (e.g., majority carriers are electrons), then the FET may be referred to as a n-type FET. If the channel is p-type (e.g., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over as one or more instructions (e.g., code) on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and modules described in connection with the disclosure herein may be implemented or performed with a processor, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or any type of processor. A processor may also be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a computer, or a processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A method, comprising:
performing an etching process on a substrate comprising a photoresist layer;
selecting at least a temperature of a clamp for holding the substrate based at least in part on performing the etching process;
generating a plasma that comprises oxygen based at least in part on selecting the temperature of the clamp for holding the substrate; and
exposing the photoresist layer of the substrate to the plasma at the selected temperature to at least partially remove the photoresist layer from the substrate.

2. The method of claim 1, further comprising:
selecting a pressure of a process chamber for housing the clamp based at least in part on performing the etching process, wherein exposing the photoresist layer of the substrate to the plasma comprises exposing the photoresist layer of the substrate to the plasma at the selected pressure to at least partially remove the photoresist layer from the substrate.

3. The method of claim 2, wherein the selected pressure comprises a pressure between 100 millitorr and 300 millitorr.

4. The method of claim 1, further comprising:
selecting a power of a plasma source for applying the plasma to the photoresist layer of the substrate based at least in part on performing the etching process, wherein exposing the photoresist layer of the substrate to the plasma comprises exposing the photoresist layer of the substrate to the plasma at the selected power to at least partially remove the photoresist layer from the substrate.

5. The method of claim 4, wherein the selected power comprises a power between 1200 watts and 1500 watts.

6. The method of claim 1, wherein the selected temperature comprises a temperature between 10 degrees Celsius and 50 degrees Celsius.

7. The method of claim 1, further comprising:
adjusting the selected temperature from a first temperature to a second temperature based at least in part on determining an operating condition of a process chamber for housing the clamp, a type of material of the substrate, or both.

8. The method of claim 1, wherein the clamp is configured to be heated to the selected temperature or cooled to the selected temperature.

9. The method of claim 1, wherein the clamp is configured to be cooled to the selected temperature.

10. The method of claim 1, wherein the clamp is configured to operate at a temperature lower than an ambient temperature of a process chamber housing the clamp.

11. A method, comprising:
performing an etching process on a substrate comprising a photoresist layer;
selecting, based at least in part on performing the etching process, a temperature of a process chamber, a pressure of the process chamber, and a power of a plasma source located in the process chamber where the etching process is performed; and
applying a plasma to the photoresist layer of the substrate at the selected temperature, pressure, and power to remove the photoresist layer from the substrate.

12. The method of claim 11, further comprising:
determining an operating condition of the process chamber, a type of material of the substrate, or both based at least in part on performing the etching process; and
adjusting at least one of the selected temperature, pressure, or power from a first value to a value based at least in part on determining the operating condition of the process chamber, the type of material of the substrate, or both, wherein applying the plasma is based at least in part on adjusting at least one of the selected temperature, the selected pressure, or the selected power.

13. The method of claim 11, wherein the selected temperature comprises a temperature between 10 degrees Celsius and 100 degrees Celsius.

14. The method of claim 11, wherein the selected pressure comprises a pressure between 100 millitorr and 500 millitorr.

15. The method of claim 11, wherein the selected power comprises a power between 1000 watts and 2000 watts.

16. An apparatus, comprising:
a process chamber configured to perform a plasma ashing process, wherein the process chamber comprises;
a clamp configured to operate at a selected temperature, pressure, and power;
a plasma source configured to generate a plasma that comprises oxygen; and
a baffle plate configure to diffuse the plasma from the plasma source over the clamp at the selected temperature, selected pressure, and selected power.

17. The apparatus of claim 16, wherein the process chamber further comprises:
a temperature component coupled with the clamp and configured to adjust a temperature of the clamp from a first temperature to the selected temperature.

18. The apparatus of claim 16, wherein the process chamber is configured to operate at a temperature less than 150 degrees Celsius.

19. The apparatus of claim 16, wherein the process chamber is configured to operate at a pressure less than 1000 millitorr.

20. The apparatus of claim 16, wherein the plasma source is configured to operate at a power less than 3000 watts.
